(19) United States
(12) Patent Application Publication
(10) Pub. No.: US 2022/0344395 A1
(43) Pub. Date: Oct. 27, 2022

(54) PHOTODETECTOR CIRCUIT WITH INDIRECT DRAIN COUPLING

(71) Applicant: Quantum-Si Incorporated, Guilford, CT (US)

(72) Inventors: Xin Wang, San Jose, CA (US); Le Huang, San Jose, CA (US)

(73) Assignee: Quantum-Si Incorporated, Guilford, CT (US)

(21) Appl. No.: 17/726,228

(22) Filed: Apr. 21, 2022

Related U.S. Application Data
(60) Provisional application No. 63/178,498, filed on Apr. 22, 2021.

(51) Int. Cl. H01L 27/146

(52) U.S. Cl. CPC H01L 27/14616; H01L 27/14614; H01L 27/14603; H01L 27/14643

(57) ABSTRACT

Aspects of the technology described herein relate to improved semiconductor-based image sensor designs. In some embodiments, an integrated circuit may comprise a photodetection region, an auxiliary region electrically coupled to the photodetection region by a first semiconductor device, and a drain region electrically coupled to the auxiliary region via a second semiconductor device. In some embodiments, a drain device may be configured with a gate controlling the flow of charge carriers to the drain region. In some embodiments, the flow of charge carriers to the drain region may occur via the second device. In some embodiments, the second device may be a diode-connected transistor. In some embodiments, the first and second semiconductor devices may advantageously decouple properties of the drain region from properties of the auxiliary region. In some embodiments, an integrated circuit may comprise a plurality of pixels and a control circuit configured to control a transfer of charge carriers in the plurality of pixels.

### CROSS-REFERENCE TO RELATED APPLICATION

This application claims the benefit of U.S. Provisional Patent Application Ser. No. 63/178,498, filed Apr. 22, 2021, entitled “PHOTODETECTOR CIRCUIT WITH INDIRECT DRAIN COUPLING,” which is incorporated herein by reference in its entirety.

### FIELD OF THE DISCLOSURE

The present disclosure relates to integrated devices and related instruments that can perform massively-parallel analyses of samples by providing short optical pulses to tens of thousands of sample wells or more simultaneously and receiving fluorescent signals from the sample wells for sample analyses. The instruments may be useful for point-of-care genetic sequencing and for personalized medicine.

### BACKGROUND

Photodetectors are used to detect light in a variety of applications. Integrated photodetectors have been developed that produce an electrical signal indicative of the intensity of incident light. Integrated photodetectors for imaging applications include an array of pixels to detect the intensity of light received from across a scene. Examples of integrated photodetectors include charge coupled devices (CCDs) and Complementary Metal Oxide Semiconductor (CMOS) image sensors.

Instruments that are capable of massively-parallel analyses of biological or chemical samples are typically limited to laboratory settings because of several factors that can include their large size, lack of portability, requirement of a skilled technician to operate the instrument, power need, need for a controlled operating environment, and cost. When a sample is to be analyzed using such equipment, a common paradigm is to extract a sample at a point of care or in the field, send the sample to the lab and wait for results of the analysis. The wait time for results can range from hours to days.

### SUMMARY OF THE DISCLOSURE

Some aspects of the present disclosure relate to an integrated circuit, comprising a photodetection region, an auxiliary region, a drain region, a first transistor channel electrically coupling the photodetection region to the auxiliary region, and a second transistor channel electrically coupling the auxiliary region to the drain region, wherein when the first transistor channel is in an on state, the second transistor channel is in an on state.

Some aspects of the present disclosure relate to an integrated circuit, comprising a photodetection region, an auxiliary region, a drain region, a drain transistor channel coupled to a drain transfer gate configured to receive a control signal, and an auxiliary transistor channel coupled to an auxiliary transfer gate, wherein when a control signal is received at the drain transfer gate, the drain and auxiliary transistor channels are configured to conduct a current from the photodetection region to the drain region via the auxiliary region.

Some aspects of the present disclosure relate to an integrated circuit, comprising a photodetection region, an auxiliary region, a drain region, a drain device electrically coupling the photodetection region to the auxiliary region, and an auxiliary device electrically coupling the auxiliary region to the drain region, wherein the auxiliary device comprises a transistor in a diode-connected configuration.

Some aspects of the present disclosure relate to a method of manufacturing an integrated circuit, the method comprising forming a photodetection region of the integrated circuit, forming an auxiliary region of the integrated circuit, forming a drain region of the integrated circuit, forming a drain device electrically coupling the photodetection region to the auxiliary region, and forming an auxiliary device electrically coupling the auxiliary region to the drain region, wherein when the drain device is in an on state, the auxiliary device is in an on state.

The foregoing summary is not intended to be limiting. In addition, various embodiments may include any aspects of the disclosure either alone or in combination.

### BRIEF DESCRIPTION OF DRAWINGS

FIG. 1-1 is a schematic of an integrated device, according to some embodiments.

FIG. 1-2 is a schematic of a pixel of the integrated device of FIG. 1-1, according to some embodiments.

FIG. 1-3 is a circuit diagram of an exemplary pixel that may be included in the integrated device of FIG. 1-1, according to some embodiments.

FIG. 1-4 is a side view of a portion of an exemplary pixel, the pixel having metal layers and vias, according to some embodiments.

FIG. 1-5 is a diagram illustrating charge transfer in the pixel of FIG. 1-3, according to some embodiments.

FIG. 1-6A is a top view of an exemplary pixel that may be included in the integrated device of FIG. 1-1, the pixel having multiple charge storage regions and a photodetection region configured to induce an intrinsic electric field, according to some embodiments.

FIG. 1-6B is a top view of an exemplary pixel that may be included in the integrated device of FIG. 1-1 according to other embodiments.

FIGS. 1-7A, 1-7B, 1-7C and 1-7D each shows a circuit diagram of an exemplary pixel that is an alternative implementation of the embodiment shown in FIG. 1-3.

FIG. 2-1A is a block diagram of an integrated device and an instrument, according to some embodiments.

FIG. 2-1B is a schematic of an apparatus including an integrated device, according to some embodiments.

FIG. 2-1C is a block diagram depiction of an analytical instrument that includes a compact mode-locked laser module, according to some embodiments.

FIG. 2-1D depicts a compact mode-locked laser module incorporated into an analytical instrument, according to some embodiments.

FIG. 2-2 depicts a train of optical pulses, according to some embodiments.

FIG. 3-1 is a cross-sectional schematic of an alternative example integrated device illustrating a row of pixels, according to some embodiments.

FIG. 3-2 is a cross-sectional view of an example pixel of the integrated device of FIG. 3-1, according to some embodiments.

The features and advantages of the present invention will become more apparent from the detailed description set forth below when taken in conjunction with the drawings. When describing embodiments in reference to the drawings, directional references (“above,” “below,” “top,” “bottom,” “left,” “right,” “horizontal,” “vertical,” etc.) may be used. Such references are intended merely as an aid to the reader viewing the drawings in a normal orientation. These directional references are not intended to describe a preferred or only orientation of features of an embodied device. A device may be embodied using other orientations.

### DETAILED DESCRIPTION

I. Introduction

Aspects of the present disclosure relate to integrated devices, instruments, and related systems capable of analyzing samples in parallel, including identification of single molecules and nucleic acid sequencing. Such an instrument may be compact, easy to carry, and easy to operate, allowing a physician or other provider to readily use the instrument and transport the instrument to a desired location where care may be needed. Analysis of a sample may include labeling the sample with one or more fluorescent markers, which may be used to detect the sample and/or identify single molecules of the sample (e.g., individual nucleotide identification as part of nucleic acid sequencing). A fluorescent marker may become excited in response to illuminating the fluorescent marker with excitation light (e.g., light having a characteristic wavelength that may excite the fluorescent marker to an excited state) and, if the fluorescent marker becomes excited, emit emission light (e.g., light having a characteristic wavelength emitted by the fluorescent marker by returning to a ground state from an excited state). Detection of the emission light may allow for identification of the fluorescent marker, and thus, the sample or a molecule of the sample labeled by the fluorescent marker. According to some embodiments, the instrument may be capable of massively-parallel sample analyses and may be configured to handle tens of thousands of samples or more simultaneously.

The inventors have recognized and appreciated that an integrated device having sample wells configured to receive the sample and integrated optics formed on the integrated device and an instrument configured to interface with the integrated device may be used to achieve analysis of this number of samples. The instrument may include one or more excitation light sources, and the integrated device may interface with the instrument such that the excitation light is delivered to the sample wells using integrated optical components (e.g., waveguides, optical couplers, optical splitters) formed on the integrated device. The optical components may improve the uniformity of illumination across the sample wells of the integrated device and may reduce a large number of external optical components that might otherwise be needed. Furthermore, the inventors have recognized and appreciated that integrating photodetection regions (e.g., photodiodes) on the integrated device may improve detection efficiency of fluorescent emissions from the sample wells and reduce the number of light-collection components that might otherwise be needed.

In some embodiments, the integrated device may be configured to receive fluorescent emission photons from the sample wells and generate and transmit charge carriers to one or more charge storage regions in response to receiving the fluorescent emission photons. For example, a photodetection region may be positioned on the integrated device and configured to receive the fluorescent emission charge carriers along an optical axis, and the photodetection region also may be coupled to one or more charge storage regions (e.g., storage diodes) along an electrical axis, such that the charge storage region(s) may collect charge carriers generated in the photodetection region in response to the fluorescent emission charge carriers. In some embodiments, the integrated device can be configured to receive one or more control signals at one or more transfer gates that control a transfer of charge carriers from the photodetection region to the charge storage region(s) for later readout.

Challenges arise in collecting fluorescent emission charge carriers in the charge storage regions due to the relatively small quantity of fluorescent emission charge carriers compared to excitation charge carriers that may reach the integrated device. For instance, excitation photons from the excitation source may reach the photodetectors and generate noise charge carriers that would be indistinguishable from fluorescent emission charge carriers if they were to reach the charge storage regions. Thus, excitation photons can add noise to detected fluorescent emissions in the photodetectors.

In some embodiments, during a drain period (e.g., preceding a collection period), a drain region of the integrated device may receive noise charge carriers (e.g., excitation charge carriers generated responsive to incident excitation photons) from the photodetection region for discarding. For example, noise charge carriers may be conducted to a direct current (DC) voltage source. In some embodiments, the drain region of the integrated device can be coupled to the photodetection region by a drain charge transfer channel. In some embodiments, the integrated device can be configured to receive a drain control signal at a drain gate that controls a transfer of charge carriers from the photodetection region to the drain region. In some embodiments, the integrated device can be configured to perform a collection sequence including a drain period; a collection period, during which charge storage region(s) may receive fluorescent emission charge carriers from the photodetection region; and a readout period, during which the charge storage region(s) may provide the stored charge carriers to a readout circuit for processing.

The inventors have recognized that, when a drain control signal is received at a drain gate of the integrated device, a voltage at the drain region can change advantageously. For example, such voltage changes can increase the electric potential gradient from the photodetection region to the drain region, thereby increasing the flow of noise charge carriers from the photodetection region to the drain region. The inventors have also recognized, however, that such changes can alter the voltage of metal lines electrically coupling, in certain embodiments, the drain region to a DC voltage source, which can cause the DC voltage received at each pixel to vary between pixels, causing inconsistency of operation in the device. Moreover, electrical (e.g., capacitive) properties of the metal lines to which, in certain embodiments, the drain region is coupled may reduce advantageous changes of voltage at the drain region.

To solve the above problems, the inventors have developed techniques to allow for advantageous voltage changes within a pixel circuit that increase drainage of noise charge carriers while reducing or eliminating voltage fluctuations in metal lines outside the pixel circuit that can introduce noise into pixel circuits and cause inconsistencies in device operation. For instance, in some embodiments a pixel described herein may have a plurality of devices, such as a drain device and an auxiliary device, situated between a photodetection region and a drain region. The drain region may be coupled to a voltage source, such as metal lines connected conductively to a direct current (DC) power supply. In some embodiments, the auxiliary device may be configured to allow the drain device to be indirectly coupled to the drain region. This indirect coupling can, in certain embodiments, allow the voltage in the region between the auxiliary and drain devices to change advantageously, which aids in causing noise charge carriers to be drained from the photodetection region, while reducing the introduction of noise into pixel circuits through metal lines.

It should be appreciated that integrated devices described herein may incorporate any or all techniques described herein alone or in combination.

II. Exemplary Integrated Device Overview

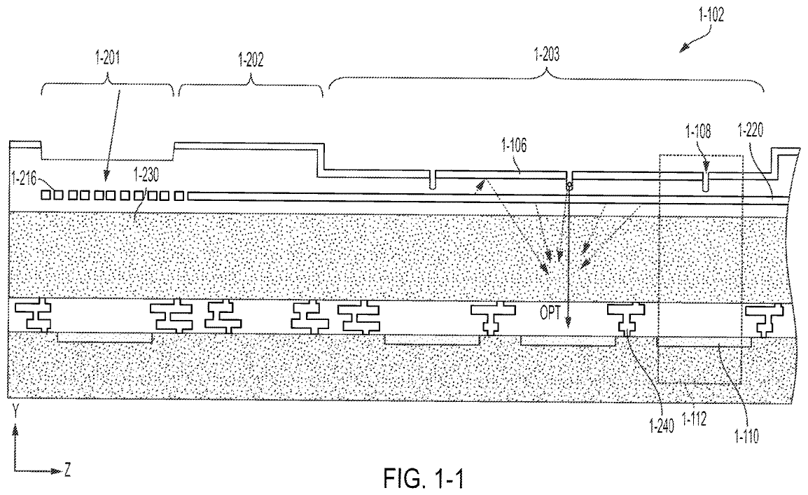

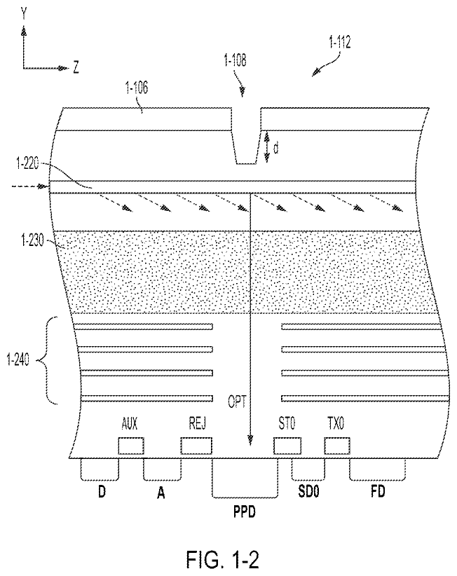

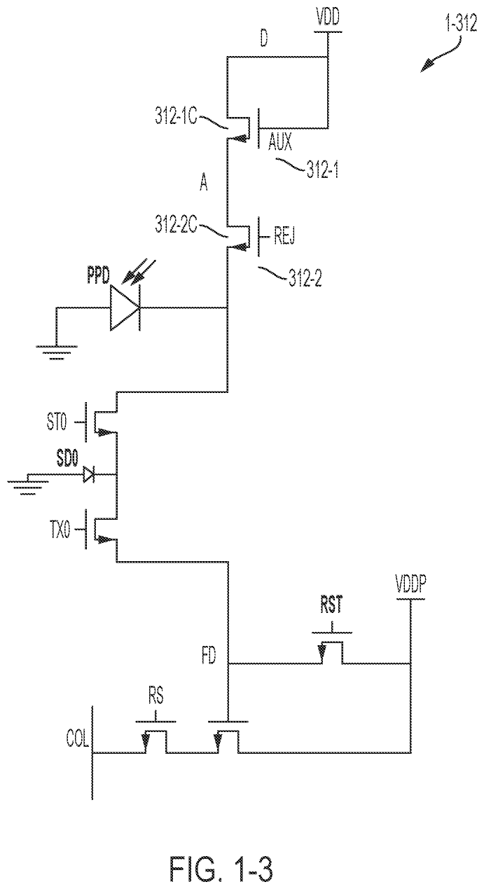

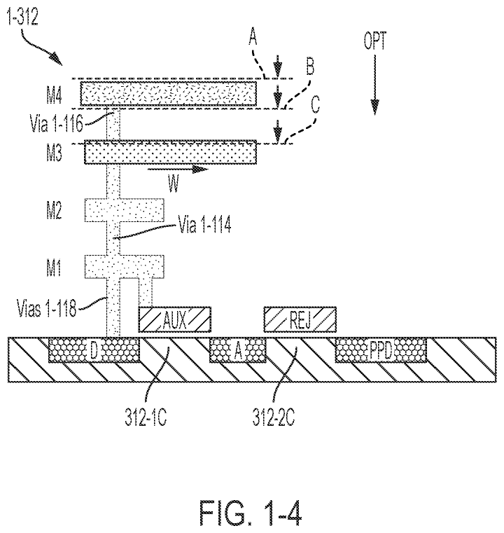

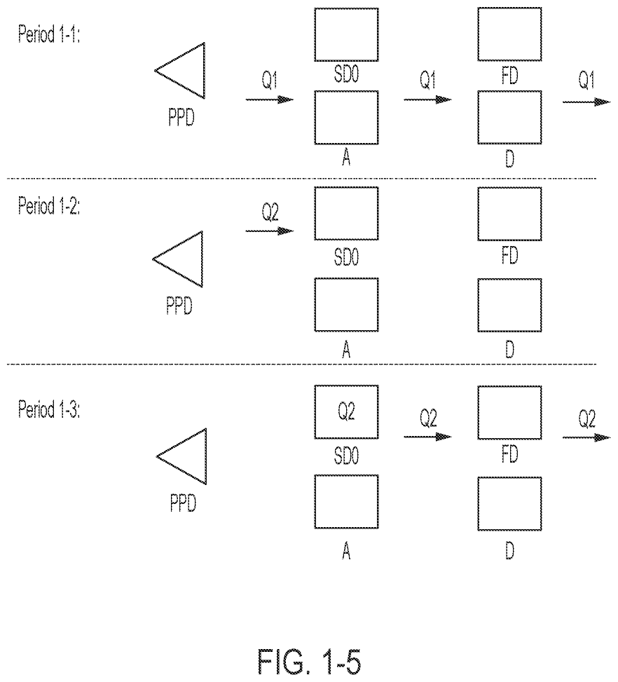

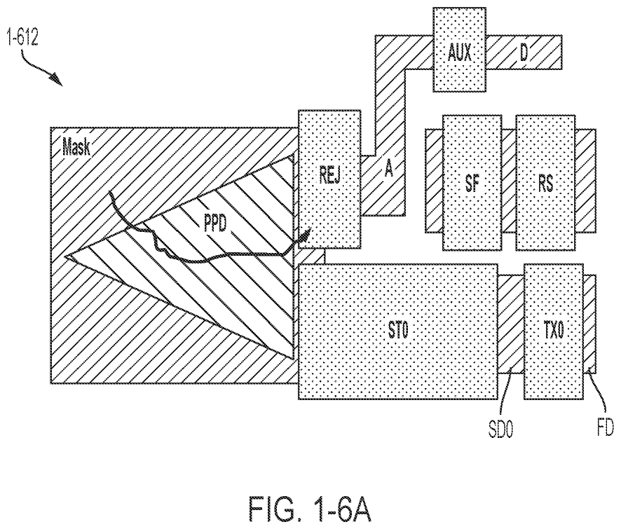

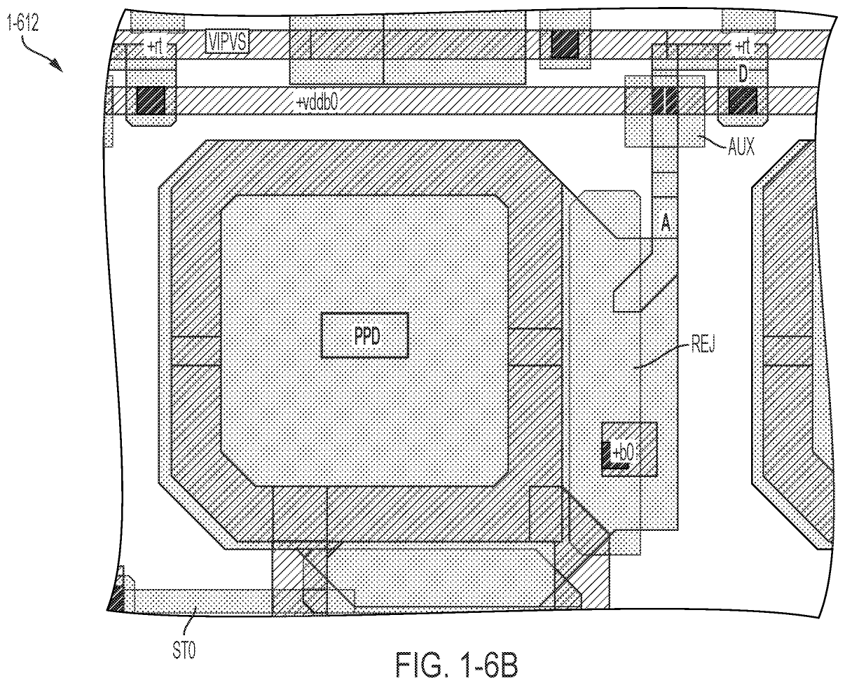

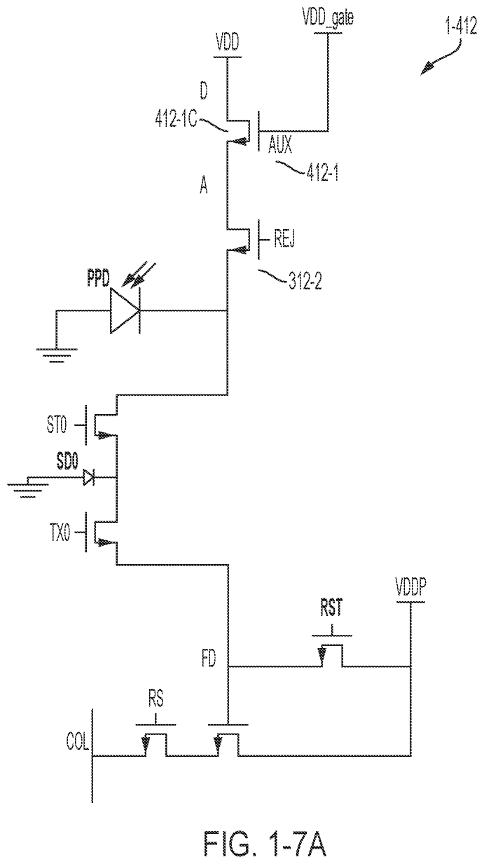

A cross-sectional schematic of integrated device 1-102 illustrating a row of pixels 1-112 is shown in FIG. 1-1. Integrated device 1-102 is an exemplary integrated device with which the drain concepts of the present innovation may be used but are not so limited. Integrated device 1-102 may include coupling region 1-201, routing region 1-202, and pixel region 1-203. Pixel region 1-203 may include a plurality of pixels 1-112 having sample wells 1-108 positioned on a surface at a location separate from coupling region 1-201, which is where excitation light (shown as the dashed arrow) couples to integrated device 1-102. Sample wells 1-108 may be formed through metal layer(s) 1-106. One pixel 1-112, illustrated by the dotted rectangle, is a region of integrated device 1-102 that includes a sample well 1-108 and one or more photodetectors 1-110 associated with the sample well 1-108. In some embodiments, each photodetector 1-110 may include a photodetection region and a drain region connected by a plurality of devices, such as a drain device and an auxiliary device, to transfer excitation charge carriers generated in response to incident light from the sample well 1-108.

FIG. 1-1 illustrates the path of excitation light by coupling a beam of excitation light to coupling region 1-201 and to sample wells 1-108. The row of sample wells 1-108 shown in FIG. 1-1 may be positioned to optically couple with waveguide 1-220. Excitation light may illuminate a sample located within a sample well. The sample may reach an excited state in response to being illuminated by the excitation light. When a sample is in an excited state, the sample may emit emission light, which may be detected by one or more photodetectors associated with the sample well. FIG. 1-1 schematically illustrates an optical axis of emission light OPT from a sample well 1-108 to photodetector(s) 1-110 of pixel 1-112. The photodetector(s) 1-110 of pixel 1-112 may be configured and positioned to detect emission light from sample well 1-108. Examples of suitable photodetectors are described in U.S. patent application Ser. No. 14/821,656 titled “INTEGRATED DEVICE FOR TEMPORAL BINNING OF RECEIVED PHOTONS,” which is incorporated herein by reference in its entirety. Alternative or additional examples of photodetectors are described further herein. For an individual pixel 1-112, a sample well 1-108 and its respective photodetector(s) 1-110 may be aligned along the optical axis OPT. In this manner, the photodetector(s) may overlap with the sample well within a pixel 1-112.

The directionality of the emission light from a sample well 1-108 may depend on the positioning of the sample in the sample well 1-108 relative to metal layer(s) 1-106 because metal layer(s) 1-106 may act to reflect emission light. In this manner, a distance between metal layer(s) 1-106 and a fluorescent marker on a sample positioned in a sample well 1-108 may impact the efficiency of photodetector(s) 1-110, that are in the same pixel as the sample well, to detect the light emitted by the fluorescent marker. The distance between metal layer(s) 1-106 and the bottom surface of a sample well 1-106, which is proximate to where a sample may be positioned during operation, may be in the range of 100 nm to 500 nm, or any value or range of values in that range. In some embodiments the distance between metal layer(s) 1-106 and the bottom surface of a sample well 1-106 is approximately 300 nm, but other distances may be used, as embodiments described herein are not so limited.

The distance between the sample and the photodetector(s) may also impact efficiency in detecting emission light. By decreasing the distance light has to travel between the sample and the photodetector(s), detection efficiency of emission light may be improved. In addition, smaller distances between the sample and the photodetector(s) may allow for pixels that occupy a smaller area footprint of the integrated device, which can allow for a higher number of pixels to be included in the integrated device. The distance between the bottom surface of a sample well 1-106 and photodetector(s) may be in the range of 5 μm to 15 μm, or any value or range of values in that range, in some embodiments, but the invention is not so limited. It should be appreciated that, in some embodiments, emission light may be provided through other means than an excitation light source and a sample well. Accordingly, some embodiments may not include sample well 1-108.

Photonic structure(s) 1-230 may be positioned between sample wells 1-108 and photodetectors 1-110 and configured to reduce or prevent excitation light from reaching photodetectors 1-110, which may otherwise contribute to signal noise in detecting emission light. As shown in FIG. 1-1, the one or more photonic structures 1-230 may be positioned between waveguide 1-220 and photodetectors 1-110. Photonic structure(s) 1-230 may include one or more optical rejection photonic structures including a spectral filter, a polarization filter, and a spatial filter. Photonic structure(s) 1-230 may be positioned to align with individual sample wells 1-108 and their respective photodetector(s) 1-110 along a common axis. Metal layers 1-240 may be configured in some embodiments to carry power supply voltages and/or control signals and/or readout signals to and/or from portions of integrated device 1-102 as described further herein.

Coupling region 1-201 may include one or more optical components configured to couple excitation light from an external or internal excitation source. Coupling region 1-201 may include grating coupler 1-216 positioned to receive some or all of a beam of excitation light. Examples of suitable grating couplers are described in U.S. Pat. Application 62/435,693 titled “OPTICAL COUPLER AND WAVEGUIDE SYSTEM,” which is incorporated herein by reference in its entirety. Grating coupler 1-216 may couple excitation light to waveguide 1-220, which may be configured to propagate excitation light to the proximity of one or more sample wells 1-108. Alternatively, coupling region 1-201 may comprise other well-known structures for coupling light into a waveguide, or directly into the sample wells.

Components located off of or within the integrated device may be used to position and align the excitation source 1-106 to the integrated device. Such components may include optical components including lenses, mirrors, prisms, windows, apertures, attenuators, and/or optical fibers. Additional mechanical components may be included in the instrument (to which the integrated device couples) to allow for control of one or more alignment components. Such mechanical components may include actuators, stepper motors, and/or knobs. Examples of suitable excitation sources and alignment mechanisms are described in U.S. patent application Ser. No. 15/161,088 titled “PULSED LASER AND SYSTEM,” which is incorporated herein by reference in its entirety. Another example of a beam-steering module is described in U.S. patent application Ser. No. 15/842,720 titled “Compact Beam Shaping and Steering Assembly,” which is incorporated herein by reference in its entirety.

A sample to be analyzed may be introduced into sample well 1-108 of pixel 1-112. The sample may be a biological sample or any other suitable sample, such as a chemical sample. The sample may include multiple molecules and the sample well may be configured to isolate a single molecule. In some instances, the dimensions of the sample well may act to confine a single molecule within the sample well, allowing measurements to be performed on the single molecule. Excitation light may be delivered into the sample well 1-108, so as to excite the sample or at least one fluorescent marker attached to the sample or otherwise associated with the sample while it is within an illumination area within the sample well 1-108.

In operation, parallel analyses of samples within the sample wells are carried out by exciting some or all of the samples within the wells using excitation light and detecting signals from sample fluorescent emissions using the photodetectors. Excitation light and fluorescent emission light from a sample may reach one or more corresponding photodetectors and generate charge carriers therein. Charge carriers generated from excitation light may be transmitted to a drain region as described herein. Charge carriers generated from fluorescent emission light may be collected in charge storage regions and later read out from the photodetector(s) as at least one electrical signal. The electrical signals may be transmitted along metal lines (e.g., of metal layers 1-240) of the integrated device, which may be connected to an instrument interfaced with the integrated device. The electrical signals may be subsequently processed and/or analyzed. Processing or analyzing of electrical signals may occur on a suitable computing device either located on or off the instrument.

III. Exemplary Pixel Overview

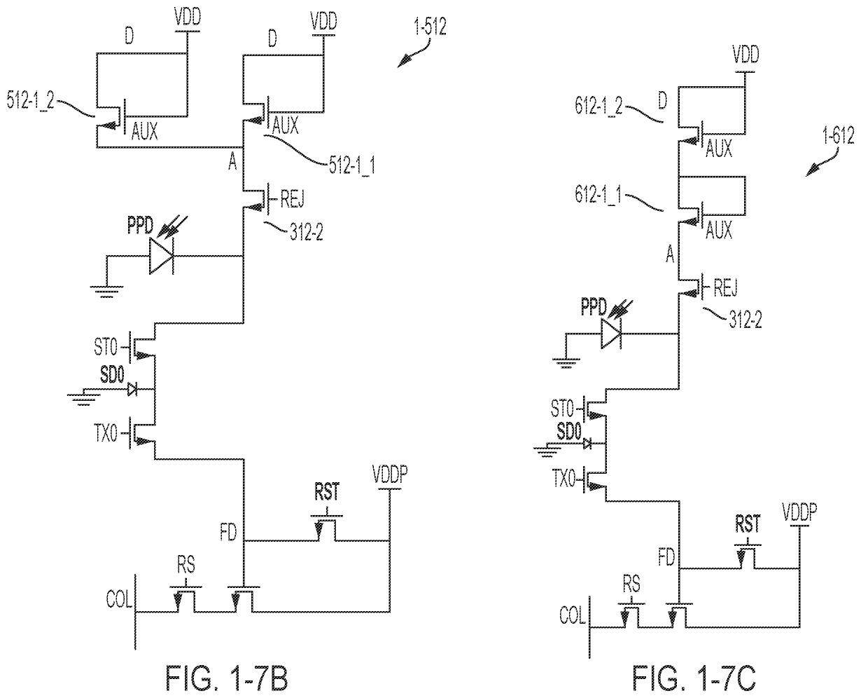

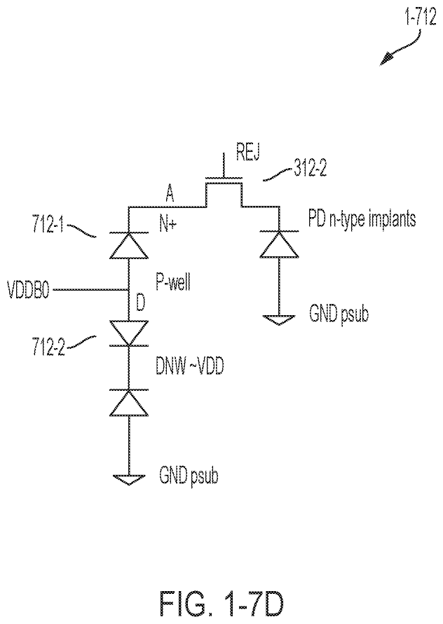

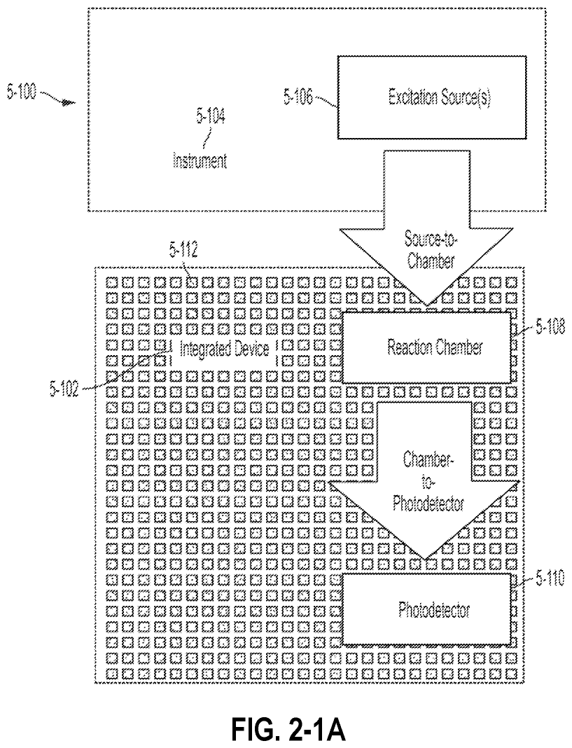

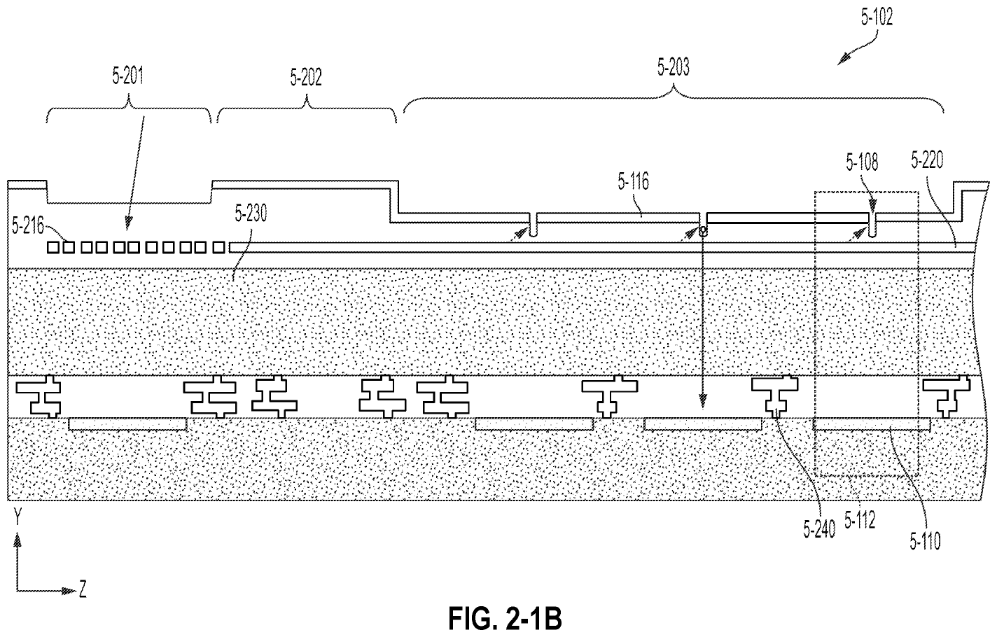

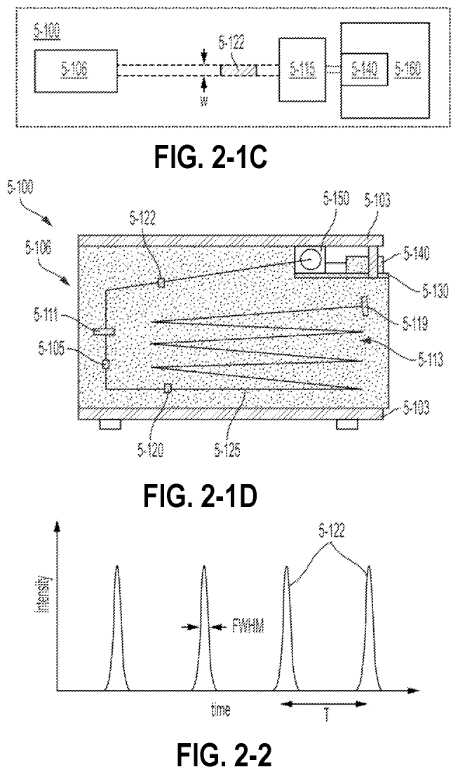

FIG. 1-2 illustrates a cross-sectional view of an exemplary pixel 1-112 with which the drain concepts of the present innovation may be used but are not so limited. Pixel 1-112 may be a pixel of exemplary integrated device 1-102 according to one embodiment. Pixel 1-112 includes a photodetection region, which may be a pinned photodiode (PPD), a drain region D, an auxiliary region A, a charge storage region, which may be a storage diode (SD0), a readout region, which may be a floating diffusion (FD) region, and transfer gates AUX, REJ, ST0, and TX0. In some embodiments, photodetection region PPD, drain region D, auxiliary region A, charge storage region SD0, and/or readout region FD may be formed in the integrated device 1-102 by doping portions of one or more substrate layers of the integrated device 1-102. For example, the integrated device 1-102 may have a lightly p-doped substrate, and photodetection region PPD, drain region D, auxiliary region A, charge storage region SD0, and/or readout region FD, may be n-doped regions of the substrate. In this example, p-doped regions may be doped using boron and n-doped regions may be doped using phosphorus, although other dopants and configurations are possible. In some embodiments, pixel 1-112 may have an area smaller than or equal to 10 micrometers by 10 micrometers, such as smaller than or equal to 7.5 micrometers×5 micrometers. It should be appreciated that, in some embodiments, the substrate may be lightly n-doped and photodetection region PPD, drain region D, auxiliary region A, charge storage region SD0, and/or readout region FD may be p-doped, as embodiments described herein are not so limited.

In some embodiments, photodetection region PPD may be configured to generate charge carriers in response to incident light. For instance, during operation of pixel 1-112, excitation light may illuminate sample well 1-108 causing incident photons, including fluorescent emissions from a sample, to flow along the optical axis OPT to photodetection region PPD, which may be configured to generate fluorescent emission charge carriers in response to the incident photons from sample well 1-108. In some embodiments, the integrated device 1-102 may be configured to transfer the charge carriers to drain region D or to charge storage region SD0. For example, during a drain period following a pulse of excitation light, the incident photons reaching photodetection region PPD may be predominantly excitation photons to be transferred to drain region D via auxiliary region A to be discarded outside the pixel circuit. In this example, during a collection period following the drain period, fluorescent emission photons may reach photodetection region PPD to be transferred to charge storage region SD0 for collection at a later period. In some embodiments, a drain period and collection period may follow each excitation pulse.

In some embodiments, auxiliary region A may be configured to receive charge carriers generated in photodetection region PPD in response to the incident light. For example, auxiliary region A may be configured to receive charge carriers generated in photodetection region PPD in response to excitation photons. In some embodiments, auxiliary region A may be electrically coupled to photodetection region PPD by a charge transfer channel. In some embodiments, the charge transfer channel may be formed by doping a region of pixel 1-112 between photodetection region PPD and auxiliary region A with a same conductivity type as photodetection region PPD and auxiliary region A such that the charge transfer channel is configured to be conductive when at least a threshold voltage is applied to the charge transfer channel and nonconductive when a voltage less than (or greater than, for some embodiments) the threshold voltage is applied to the charge transfer channel. In some embodiments, the threshold voltage may be a voltage above (or below) which the charge transfer channel is depleted of charge carriers, such that charge carriers from photodetection region PPD may travel through the charge transfer channel to auxiliary region A. For example, the threshold voltage may be determined based on the materials, dimensions, and/or doping configuration of the charge transfer channel.

In some embodiments, transfer gate REJ may be configured to control a transfer of charge carriers from photodetection region PPD to auxiliary region A. For instance, transfer gate REJ may be configured to receive a control signal and responsively determine a conductivity of a charge transfer channel electrically coupling photodetection region PPD to auxiliary region A. For example, excitation photons from the excitation light source may reach photodetection region PPD before fluorescent emission photons from the sample well 1-108 reach photodetection region PPD. In some embodiments, the integrated device 1-102 may be configured to control transfer gate REJ to transfer charge carriers, generated in photodetection region PPD in response to the excitation photons, to auxiliary region A (and subsequently to drain region D, as explained below) during a drain period following an excitation light pulse and preceding reception of fluorescent emission charge carriers. For example, when a first portion of a control signal is received at transfer gate REJ, transfer gate REJ may be configured to bias the charge transfer channel below its threshold voltage, causing the charge transfer channel to be nonconductive, such that charge carriers are blocked from reaching auxiliary region A. Alternatively, when a second portion of the control signal is received at transfer gate REJ, transfer gate REJ may be configured to bias the charge transfer channel above its threshold voltage to cause the charge transfer channel to be conductive, such that charge carriers may flow from photodetection region PPD to auxiliary region A via the charge transfer channel. In some embodiments, transfer gate REJ may be formed of an electrically conductive and at least partially opaque material such as polysilicon.

In some embodiments, transfer gate AUX may be configured to control a transfer of charge carriers from auxiliary region A to drain region D. For instance, transfer gate AUX may be configured to determine a conductivity of a charge transfer channel electrically coupling auxiliary region A to drain region D. In some embodiments, drain region D may be coupled to a voltage source, such as a direct current (DC) power supply. Due to the voltage supplied to drain region D in some embodiments, charge carriers will be drawn during a drain period from photodetection region PPD to drain region D via auxiliary region A. In some embodiments, transfer gate AUX and the charge transfer channel electrically coupling auxiliary region A to drain region D may be arranged in a diode-connected configuration, such that transfer gate AUX together with the charge transfer channel electrically coupling auxiliary region A to drain region D collectively function essentially as a device having two terminals. As one example of a diode-connected configuration, transfer gate AUX may be conductively coupled to drain region D. In some configurations, the voltage at auxiliary region A will be different from (e.g., higher than) the voltage at drain region D.

The inventors have recognized that electrically coupling auxiliary region A to drain region D via an auxiliary device can enhance the efficiency with which noise charge carriers can be transferred to drain region D for discarding, while mitigating noise in the metal lines electrically coupling drain region D to the DC power supply voltage VDD. For example, the inventors recognized that, when a drain control signal is received at drain gate REJ, the voltage potential between photodetection region PPD and auxiliary region A can change advantageously, causing a faster flow of noise charge carriers from photodetection region PPD to auxiliary region A. Because auxiliary region A is indirectly coupled to drain region D via an auxiliary device, such desirable voltage changes in auxiliary region A can occur to a greater extent than if auxiliary region A were conductively coupled to drain region D and thereby to the attached metal lines, which typically have significant capacitance. Moreover, in this example wherein auxiliary gate AUX is conductively coupled to the drain region D, the auxiliary transistor can be configured to prevent voltage fluctuations at auxiliary region A from reaching drain region D and thus from adding DC noise to the metal lines coupled to drain region D. Thus, the exemplary configuration shown in FIG. 1-2 can be configured to quickly transfer charge carriers from photodetection region PPD to drain region D while mitigating the impact of any resulting DC noise on the integrated device.

In some embodiments, transfer gate ST0 may be configured to control a transfer of charge carriers from photodetection region PPD to storage region SD0 in the manner described for transfer gate REJ in connection with photodetection region PPD and charge auxiliary region A. Charge storage region SD0 may be configured to receive and store charge carriers generated in photodetection region PPD in response to fluorescent emission photons from the sample well 1-108. In some embodiments, charge storage region SD0 may be electrically coupled to photodetection region PPD by a charge transfer channel, formed in the manner described above in connection with the charge transfer channel coupled between auxiliary region A and photodetection region PPD.

In some embodiments, transfer gate TX0 may be configured to control a transfer of charge carriers from charge storage region SD0 to readout region FD in the manner described for transfer gate REJ in connection with photodetection region PPD and auxiliary region A. For example, following a plurality of collection periods during which charge carriers are transferred from photodetection region PPD to charge storage region SD0, a readout period may occur in which charge carriers stored in charge storage region SD0 may be transferred to readout region FD to be read out to other portions of the integrated device 1-102 for processing. Some embodiments may have multiple storage regions (SD0, SD1, . . . ) and multiple transfer gates (ST0, ST1, . . . ) and (TX0, TX1, . . . ) controlling transfer of charge carriers to a storage region and to readout region FD.

In some embodiments, pixel 1-112 may be electrically coupled to a control circuit of integrated device 1-102 and configured to receive control signals at transfer gates such as REJ, ST0, and TX0. For example, metal lines of metal layers 1-240 may be configured to carry the control signals to pixels 1-112 of the integrated device 1-102. In some embodiments, a single metal line carrying a control signal may be electrically coupled to a plurality of pixels 1-112, such as an array, subarray, row, and/or column of pixels 1-112. For example, each pixel 1-112 in an array may be configured to receive a control signal from a same metal line and/or net such that the row of pixels 1-112 is configured to drain and/or collect charge carriers from photodetection region PPD at the same time. Alternatively or additionally, each row of pixels 1-112 in the array may be configured to receive different control signals (e.g., row-select signals) during a readout period such that the rows read out charge carriers one row at a time.

FIG. 1-3 is a circuit diagram of an exemplary pixel 1-312 that may be included in integrated device 1-102, according to some embodiments. In some embodiments, pixel 1-312 may be configured in the manner described for pixel 1-112. For example, as shown in FIG. 1-3, pixel 1-312 includes photodetection region PPD, drain region D, auxiliary region A, charge storage region SD0, readout region FD, and transfer gates AUX, REJ, ST0, and TX0. In FIG. 1-3, transfer gate REJ is the gate of a drain transistor 312-2 having a drain transistor channel 312-2C coupling photodetection region PPD to auxiliary region A, AUX is the gate of an auxiliary transistor 312-1 having an auxiliary transistor channel 312-1C coupling auxiliary region A to drain region D, transfer gate ST0 is the gate of a transistor coupling photodetection region PPD to charge storage region SD0, and transfer gate TX0 is the gate of a transistor coupling charge storage region SD0 to readout region FD. Pixel 1-312 also includes a reset (RST) transfer gate and a row-select (RS) transfer gate.

As shown in FIG. 1-3, auxiliary transistor 312-1 is configured in a diode-connected configuration, with its drain electrode D electrically coupled to transfer gate AUX, such that transfer gate AUX together with the auxiliary transistor channel 312-1C electrically couple auxiliary region A to drain region D, and auxiliary transistor 312-1 functions essentially as a device having two terminals.

In some embodiments, transfer gate REJ may be configured to, in response to a control signal, drain charge carriers in photodetection region PPD to a location outside the pixel. For example, transfer gate REJ may change from an “off” state to an “on” state, causing charge carriers to flow from photodetection region PPD via auxiliary region A, transfer gate AUX, and drain region D to a DC power supply voltage VDD. In the embodiment depicted in FIG. 1-3, auxiliary gate AUX is conductively coupled to drain region D, causing, in some embodiments, the transistor coupling auxiliary region A to drain region D to turn on and off based on voltages at the drain and auxiliary regions located at the transistor's drain and source, respectively. In some embodiments, the transistor coupling auxiliary region A to drain region D will be in an “on” state when, and only when, the transistor coupling the photodetection region PPD to auxiliary region A is in an “on” state.

In some embodiments, transfer gate RST may be configured to, in response to a reset control signal, clear charge carriers in readout region FD and/or charge storage region SD0. For example, transfer gate RST may be configured to enter an “on” state, causing charge carriers to flow from readout region FD and/or from charge storage region SD0 via transfer gate TX0 and readout region FD, to a DC supply voltage VDDP. In some embodiments, transfer gate RS may be configured to, in response to a row select control signal, transfer charge carriers from readout region FD to a bitline COL for processing.

While the transistors shown in FIG. 1-3 are field effect transistors (FETs) or metal-oxide semiconductor FETs (MOSFETs), it should be appreciated that aspects of the present disclosure are not limited to implementation solely using MOSFETs and that other types of transistors may be used. For example, bipolar junction transistors (BJTs) or junction FETs (JFETs) may be used to implement some or all of the transistors in the auxiliary device as described herein.

It should also be appreciated that control signals described herein applied to the various transfer gates may vary in shape and/or voltage, such as depending on the electric potential of the semiconductor region and of the regions electrically coupled to the semiconductor region (e.g., neighboring regions). Examples of control signals that may be applied to some of the transfer gates are described in U.S. patent application Ser. No. 17/507,585, titled “INTEGRATED CIRCUIT WITH SEQUENTIALLY-COUPLED CHARGE STORAGE AND ASSOCIATED TECHNIQUES,” filed Oct. 21, 2021, which is incorporated herein by reference in its entirety.

FIG. 1-4 is a side view of pixel 1-312 in some embodiments, showing metal lines and vias connecting components in pixel 1-312. For example, as shown in FIG. 1-4, pixel 1-312 includes photodetection region PPD, drain region D, auxiliary region A, transfer gates AUX and REJ, metal lines M4, M3, M2, M1, and vias 1-116, 1-114, and 1-118. In some embodiments, vias 1-114, 1-116, and/or 1-118 can be through-silicon vias (TSVs). In FIG. 1-4, transfer gate REJ is the gate of a transistor coupling photodetection region PPD to auxiliary region A, and AUX is the gate of the auxiliary transistor 312-1 coupling auxiliary region A to drain region D. In some embodiments, drain region D may be connected to a power supply voltage VDD, such as a direct current (DC) voltage. Each of transfer gates AUX, REJ may be separated from respective transistor channel 312-1C, 312-2C by one or more gate dielectric layers. While FIG. 1-4 illustrates transfer gates AUX, REJ as a unitary block, it is for illustrative purpose only. Each of transfer gates AUX, REJ may comprise any suitable material composition including uniform or a composite of multiple materials, and be of any suitable shape or dimension, as aspects of the present disclosure are not so limited.

In some embodiments, transfer gate REJ may be configured to, in response to a control signal, drain charge carriers in photodetection region PPD. For example, transfer gate REJ may cause charge carriers to flow from photodetection region PPD via auxiliary region A, transfer gate AUX, and drain region D to supply voltage VDD. In the embodiment depicted in FIG. 1-4, auxiliary gate AUX is conductively coupled to metal line M1 by vias 1-118, and drain region D is likewise conductively coupled to metal line M1 by vias 1-118, thereby conductively coupling drain region D to transfer gate AUX, such as described above in connection with FIG. 1-3. Metal line M1 in FIG. 1-4 is conductively connected to metal lines above it, such as M2 and M3, by via 1-114. As described above in connection with FIG. 1-1, metal lines 1-240 can carry voltages from a power supply and can be configured as depicted in FIG. 1-4 for metal lines M1, M2, M3, and/or M4 to provide power supply voltage VDD to drain region D and/or transfer gate AUX. In some embodiments, multiple vias 1-116 connect metal lines M4 and M3, such as for providing the DC power supply voltage to multiple pixels. It should be appreciated that configurations of metal lines, nets, and vias can be included other than those shown in FIG. 1-4, as embodiments described herein are not so limited.

FIG. 1-5 is a diagram showing exemplary charge transfer in pixel 1-312, according to some embodiments. In some embodiments, operation of pixel 1-312 may include one or more drain sequences and one or more collection sequences. In some embodiments, each collection period of the collection sequence may be preceded by a drain period, as described further herein. An exemplary collection sequence is shown in FIG. 1-5 including a drain period 1-1, a collection period 1-2, and a readout period 1-3. In some embodiments, operation of pixel 1-312 may include one or multiple iterations of the collection sequence shown in FIG. 1-5. In some embodiments, the collection sequence may be coordinated with the excitation of samples in the sample wells 1-108. For example, a single control circuit may be configured to control the excitation light source and operation of pixels 1-312.

In some embodiments, excitation photons may reach photodetection region PPD during a drain period 1-1 immediately following the excitation pulse but before collection period 1-2. For example, drain period 1-1 may occur in response to a pulse of excitation light that illuminates a sample well 1-208. During drain period 1-1 charge carriers generated in photodetection region PPD in response to the excitation photons may be transferred to auxiliary region A, thereby to drain region D, and thereby to a connected voltage source. Photodetection region PPD may be configured to generate charge carriers Q1 in response to the incident excitation photons and transfer charge carriers Q1 to auxiliary region A for draining. In some embodiments, the collection period 1-2 may include receiving a plurality of fluorescent emission photons at photodetection region PPD. For example, collection period 1-2 may occur in response to a pulse of excitation light that illuminates a sample well 1-208 configured to emit fluorescent emission photons toward photodetection region PPD. As shown in FIG. 1-5, photodetection region PPD may be configured to generate charge carriers Q2 in response to the incident fluorescent emission photons and transfer charge carriers Q2 to charge storage region SD0 during the collection period 1-2. In some embodiments, collection period 1-2 may be repeated multiple times in response to multiple respective excitation pulses, and charge carriers Q2 may be accumulated in charge storage region SD0 over the course of the collection periods 1-2. In some such embodiments, each collection period 1-2 may be preceded by a drain period. In some embodiments, the drain periods 1-1 may occur at the same time for each pixel of an array, subarray, row, and/or column of the integrated device 1-102. Similarly, the collection periods 1-2 may occur at the same time for each pixel in a grouping of pixels.

In some embodiments, the readout period 1-3 may occur following one or more collection periods 1-2 during which charge carriers Q2 are accumulated in charge storage region SD0. As shown in FIG. 1-5, during the readout period 1-3, charge carriers Q2 stored in charge storage region SD0 may be transferred to readout region FD to be read out for processing. In some embodiments, the readout period 1-3 may be performed using correlated double sampling (CDS) techniques. For example, a first voltage of readout region FD may be read out at a first time, followed by a reset of the readout region FD (e.g., by applying a reset signal to transfer gate RST) and the transfer of charge carriers Q2 from charge storage region SD0 to readout region FD, and a second voltage of readout region FD may be read out at a second time following the transfer of charge carriers Q2. In this example, the difference between the first and second voltages may indicate a quantity of charge carriers Q2 transferred from charge storage region SD0 to readout region FD. In some embodiments, the readout period 1-3 may occur at a different time for each row, column, and/or pixel of an array. For example, by reading out pixels one row or column at a time, a single processing line may be configured to process readout of each row or column in sequence rather than dedicating a processing line to each pixel to read out simultaneously. In other embodiments, each pixel of an array may be configured to read out at the same time, as a processing line may be provided for each pixel of the array. According to various embodiments, charge carriers read out from the pixels may indicate fluorescence intensity, lifetime, spectral, and/or other such fluorescence information of the samples in the sample wells 1-208. In some embodiments, multiple charge storage regions (SD0, SD1, . . . ) may be included in the integrated device, configured for storage and readout in the manner described above for pixel 1-312.

FIG. 1-6A is a top view of pixel 1-612, which may be included in integrated device 1-102, according to some embodiments. In some embodiments, pixel 1-612 may be configured in the manner described herein for pixels 1-112. For example, in FIG. 1-6A, pixel 1-612 includes photodetection region PPD, auxiliary region A, drain region D, charge storage region SD0, readout region FD, and transfer gates REJ, AUX, ST0, TX0, RST, and RS. Drain region D may be coupled to a voltage supply, and noise charge carriers (such as photoelectrons) may be drained from the photodetection region PPD via transfer gate REJ, auxiliary region A, transfer gate AUX, and drain region D. In some embodiments, a multiplicity of gates and regions between photodetection region PPD and drain region D are present. In some embodiments, pixel 1-612 may include a second charge storage region SD1 and transfer gates ST1 and TX1, which may be configured in the manner described herein for charge storage region SD0 and transfer gates ST0 and TX0, respectively. For example, charge storage regions SD0 and SD1 may be configured to receive charge carriers generated in photodetection region PPD, which may be transferred to readout region FD. In some embodiments, a separate readout region FD may be coupled to each charge storage region. It should be appreciated that, according to various embodiments, pixels described herein may include any number of charge storage regions. In some embodiments, pixel 1-612 may include a photodetection region configured to induce an intrinsic electric field in a direction from the photodetection region to the auxiliary region and/or a charge storage region.

Increasing the rate of charge transfer in a pixel can improve the noise performance of the pixel, as described further herein. For instance, it can be desirable to drain as many excitation charge carriers generated in the photodetection region in response to excitation photons as possible before fluorescent emission charge carriers reach the pixel to prevent the excitation charge carriers from being transported to the charge storage region as noise. Moreover, it can be desirable to transport fluorescent emission charge carriers generated in the photodetection region in response to fluorescent photons to the appropriate charge storage region as quickly as possible to ensure the accuracy of charge readouts from the pixel.

Accordingly, it can be advantageous to induce an intrinsic electric field in the photodetection region of a pixel to increase the rate at which charge carriers are transferred out from the photodetection region to the appropriate location in the pixel (e.g., auxiliary region or charge storage region). In some embodiments, a pixel described herein may include a photodetection region configured to induce an intrinsic electric field in a direction from the photodetection region to the auxiliary region and/or a charge storage region. For example, the electric field may exert a force that causes charge carriers to travel more quickly from the photodetection region to the auxiliary region (in the direction of drain region D) and/or the charge storage region than without the intrinsic electric field. In some embodiments, the auxiliary region and charge storage region may be positioned on a same side of the photodetection region, such as the embodiment depicted in FIG. 1-6A, such that the intrinsic electric field may increase the rate of charge transfer to each of the drain and charge storage regions.

According to one example, a photodetection region may include a dopant pattern configured to induce the intrinsic electric field. In this example, the dopant pattern may be formed by placing a mask with a shaped opening over the photodetection region during at least a portion of doping of the photodetection region. By inducing an intrinsic electric field in the photodetection region, the rate at which charge carriers are transferred out from the photodetection region may be increased, thereby decreasing the number of excitation photons and increasing the number of fluorescent emission photons that reach the charge storage region(s), and resulting in an increase in the signal to noise ratio of charge readouts from the pixel.

FIG. 1-6A is a schematic view of an exemplary pixel 1-612 comprising a photodetection region PPD configured to induce an intrinsic electric field, according to some embodiments. Pixel 1-612 may be configured in the manner described above for pixels 1-112 and/or in connection with FIGS. 1-1 to 1-5. As shown in FIG. 1-6A, photodetection region PPD of pixel 1-612 may be configured to induce an intrinsic electric field from photodetection region PPD to auxiliary region A and charge storage region SD0. For example, photodetection region PPD is shown in FIG. 1-6A having a dopant configuration that may be configured to induce a potential gradient due to a gradient in the dopant configuration. For instance, photodetection region PPD may have a higher number of dopants at the end of photodetection region PPD proximate auxiliary region A and charge storage region SD0 than at the opposite end of photodetection region PPD, thereby causing a potential gradient from end to end.

Increasing the rate of charge carrier transport in the pixel 1-612 increases the fluorescence-to-excitation rejection ratio of the pixel 1-612 by draining excitation charge carriers faster and accumulating more fluorescent emission charge carriers in the charge storage region(s). As a result, the ratio of fluorescent emission signals to excitation noise may be improved for more accurate measurement of fluorescent information.

FIG. 1-6B is a top view of pixel 1-612, which may be included in integrated device 1-102 according to an alternative embodiment. In the embodiment depicted in FIG. 1-6B, pixel 1-612 includes photodetection region PPD, auxiliary region A, drain region D, charge storage region SD0 (not shown in FIG. 1-6B), and transfer gates REJ, AUX, and ST0. Drain region D may be coupled to a voltage supply, and noise charge carriers (such as photoelectrons) may be drained from the photodetection region PPD via transfer gate REJ, auxiliary region A, transfer gate AUX, and drain region D.

While FIG. 1-3 shows a single diode-connected auxiliary transistor 312-1, it should be appreciated that it is not a requirement. Additional or alternative component arrangements may be provided in the auxiliary device.

FIG. 1-7A is a circuit diagram of an exemplary pixel 1-412A that is an alternative implementation of the embodiment shown in FIG. 1-3. Pixel 1-412A differs from pixel 1-312 in that unlike the diode-connected configuration of auxiliary transistor 312-1, the drain region D for auxiliary transistor 412-1 is not electrically coupled to the auxiliary transfer gate AUX. While the drain region D is connected to VDD, the transfer gate AUX may be separated provided with a gate control signal VDD_gate, for example from the control circuit (not shown). VDD_gate may be configured to have a timing based on control signal provided to the drain transfer gate REJ, and to cause the auxiliary transistor channel 412-1C to be on or off at a similar timing to the transistor 312-1, such that the auxiliary transistor channel 412-1C will be in an “on state” when the drain transistor 312-2 is in an “on” state to conduct a current from the photodetection region to the drain region via the auxiliary region. According to one non-limiting example, the gate voltage VDD_gate may be set such that transfer gate AUX will cause auxiliary transistor channel 412-1C to be on when a control signal at the drain transfer gate REJ causes drain transistor 312-2 to be off. In this example, when the REJ gate is on, the electrical potential in the region “A” will be boosted due to conductive coupling to the REJ gate. With “A” region potential increasing, the AUX gate will partially or fully turn auxiliary transistor channel 412-1C off since the gate/source voltage difference is reduced. With this approach, the “A” region has relatively lower capacitance, so the boosted voltage can be higher to facilitate the charge transfer of the REJ gate. As an additional benefit, the voltage disturbance to the VDD may be reduced.

FIG. 1-7B is a circuit diagram of an exemplary pixel 1-512 that is another alternative implementation of the embodiment shown in FIG. 1-3. Pixel 1-512 differs from pixel 1-312 in that two parallel auxiliary transistors 512-1_1, 512-1_2 are provided that each couples the drain region D with the auxiliary region A. Any suitable number of parallel auxiliary transistors may be provided. Each of auxiliary transistors 512-1_1, 512-1_2 is in a diode-connected configuration such that their transistor channels will be in an “on state” when the drain transistor 312-2 is in an “on” state to conduct a current from the photodetection region to the drain region via the auxiliary region.

FIG. 1-7C is a circuit diagram of an exemplary pixel 1-612 that is another alternative implementation of the embodiment shown in FIG. 1-3. Pixel 1-612 differs from pixel 1-312 in that two serial auxiliary transistors 612-1_1, 612-1_2 are provided. In FIG. 1-7C, the drain region D is coupled to the auxiliary region A via the two serially connected auxiliary transistors. Any suitable number of serial auxiliary transistors may be provided. Each of auxiliary transistors 612-1_1, 612-1_2 is in a diode-connected configuration such that their transistor channels will be in an “on state” when the drain transistor 312-2 is in an “on” state to conduct a current from the photodetection region to the drain region via the auxiliary region.

FIG. 1-7D is a circuit diagram of an exemplary pixel 1-712 that is another alternative implementation of the embodiment shown in FIG. 1-3, without using a transistor in the auxiliary device. Instead of using a diode-connected auxiliary transistor 1-312, FIG. 1-7D shows that a diode 712-1 electrically couples the auxiliary region A to the drain region D. As shown, a cathode of diode 712-1 is coupled to the auxiliary region A, while an anode of diode 712-1 is coupled to the drain region D and voltage VDDB0. Preferably voltage VDDB0 is smaller than VDD, for example smaller than VDD by about 0.6 V, such that the p-well drain n-well diode 712-2 is not forward biased.

IV. DNA, RNA, and Protein Sequencing Applications

An analytic system described herein may include an integrated device and an instrument configured to interface with the integrated device, for example a biological sequencing instrument. As described above, the integrated device may include an array of pixels, where a pixel includes a sample well and at least one photodetector. A sample well may be configured to receive a sample from a suspension placed on the surface of the integrated device.

Some aspects of the present disclosure may be useful for DNA or RNA sequencing. In some embodiments, a suspension may contain multiple single-stranded DNA templates. The suspension may also contain labeled nucleotides which then enter in the reaction chamber and may allow for identification of a nucleotide as it is incorporated into a strand of DNA complementary to the single-stranded DNA template in the reaction chamber.

Some aspects of the present disclosure may be useful for protein sequencing, such as determining amino acid sequence information from polypeptides. In some embodiments, amino acid sequence information can be determined for single polypeptide molecules. In some embodiments, one or more amino acids of a polypeptide are labeled, and the relative positions of the labeled amino acids in the polypeptide are determined, for example using a series of amino acid labeling and cleavage steps. In some embodiments, the identities of amino acids are assessed. Some aspects of the present disclosure provide a method of sequencing a polypeptide by detecting luminescence of a labeled polypeptide which is subjected to repeated cycles of terminal amino acid modification and cleavage.

In some embodiments, methods provided herein may be used for the sequencing and identification of an individual protein in a sample comprising a complex mixture of proteins. Sequencing in accordance with some embodiments can involve immobilizing a polypeptide on a surface of a substrate or solid support, such as a chip or integrated device. In some embodiments, a polypeptide can be immobilized on a surface of a sample well on a substrate. In some embodiments, each of a plurality of polypeptides is attached to one of a plurality of sample wells, for example in an array of sample wells on a substrate.

A schematic overview of the system 5-100 is illustrated in FIG. 2-1A. The system comprises both an integrated device 5-102 that interfaces with an instrument 5-104. In some embodiments, integrated device 5-102 may be configured in similar manner to integrated device 1-102, described above. In some embodiments, instrument 5-104 may include one or more excitation sources 5-106 integrated as part of instrument 5-104. The excitation source 5-106 may be configured to provide excitation light to the integrated device 5-102. As illustrated schematically in FIG. 2-1A, the integrated device 5-102 has a plurality of pixels 5-112, where at least a portion of pixels may perform independent analysis of a sample of interest. A pixel 5-112 has a sample well or reaction chamber 5-108 configured to receive a single sample of interest and a photodetector 5-110 for detecting emission light emitted from the reaction chamber in response to illuminating the sample and at least a portion of the reaction chamber 5-108 with excitation light provided by the excitation source 5-106.

Integrated device 5-102 may have any suitable number of pixels. In some embodiments, the number of pixels in integrated device 5-102 may be in the range of approximately 10,000 pixels to 100,000,000 pixels or any value or range of values within that range. The interface of instrument 5-104 may position integrated device 5-102 to couple with circuitry of instrument 5-104 to allow for readout signals from one or more photodetectors to be transmitted to instrument 5-104. Integrated device 5-102 and instrument 5-104 may include multi-channel, high-speed communication links for handling data associated with large pixel arrays (e.g., more than 10,000 pixels).

A cross-sectional schematic of integrated device 5-102 illustrating a row of pixels 5-112 is shown in FIG. 2-1B. In certain embodiments, pixels 5-112 may be configured in like fashion to pixel 1-112, 1-312, or 1-612 described above. Excitation light may illuminate a sample located within a sample well or reaction chamber. When in an excited state, the sample may emit emission light, which may be detected by one or more photodetectors associated with the reaction chamber.

Instrument 5-104 may include a user interface for controlling operation of instrument 5-104 and/or integrated device 5-102. The user interface may be configured to allow a user to input information into the instrument, such as commands and/or settings used to control the functioning of the instrument. In some embodiments, instrument 5-104 may include a computer interface configured to connect with a computing device, such as a laptop or desktop computer or a server. The computer interface may be a USB interface, a FireWire interface, or any other suitable computer interface. The computing device may send and/or receive via the computer interface input information for controlling or configuring the instrument 5-104 and/or output information generated by instrument 5-104.

Referring to FIG. 2-1C, a portable, advanced analytic instrument 5-100 can comprise one or more pulsed optical sources 5-106 mounted as a replaceable module within, or otherwise coupled to, the instrument 5-100. The portable analytic instrument 5-100 can include an optical coupling system 5-115 and an analytic system 5-160. The optical coupling system 5-115 can be configured to couple output optical pulses 5-122 from the pulsed optical source 5-106 to the analytic system 5-160. The analytic system 5-160 can direct the optical pulses to at least one sample well or reaction chamber for sample analysis, receive one or more optical signals (e.g., fluorescence, backscattered radiation) from the at least one reaction chamber, and produce one or more electrical signals representative of the received optical signals. In some embodiments, the analytic system 5-160 can include one or more photodetectors and may also include signal-processing electronics. The analytic system 5-160 can also include data transmission hardware configured to transmit and receive data to and from external devices.

FIG. 2-1D depicts a further example of a portable analytical instrument 5-100 that includes a compact pulsed optical source 5-113. In some cases, the analytic instrument 5-100 is configured to receive a removable, packaged, bio-optoelectronic or optoelectronic chip 5-140. The chip 5-140 can contain, for example, reaction chambers, integrated optical components arranged to deliver optical excitation energy to the reaction chambers, and integrated photodetectors arranged to detect fluorescent emission from the reaction chambers. In some implementations, the chip 5-140 can be disposable after a single use.

In some embodiments, the chip 5-140 can be mounted on an electronic circuit board 5-130 that can include additional instrument electronics. For example, the PCB 5-130 can include circuitry configured to provide electrical power, one or more clock signals, and control signals to the optoelectronic chip 5-140, and signal-processing circuitry arranged to receive signals representative of fluorescent emission detected from the reaction chambers. Data returned from the optoelectronic chip can be processed in part or entirely by electronics on the instrument 5-100, although data may be transmitted via a network connection to one or more remote data processors, in some implementations.

FIG. 2-2 depicts temporal intensity profiles of the output pulses 5-122, though the illustration is not to scale. In some embodiments, the peak intensity values of the emitted pulses may be approximately equal, and the profiles may have a Gaussian temporal profile, though other profiles such as a sech2 profile may be possible. The duration of each pulse may be characterized by a full-width-half-maximum (FWHM) value, as indicated in FIG. 2-2. According to some embodiments of a mode-locked laser, ultrashort optical pulses can have FWHM values between approximately 5 picoseconds (ps) and approximately 30 ps.

The output pulses 5-122 can be separated by regular intervals T. For example, T can be determined by a round-trip travel time between the output coupler 5-111 and cavity end mirror 5-119. In some embodiments, the pulse-separation interval corresponds to a round trip travel time in the laser cavity, so that a cavity length of 3 meters (round-trip distance of 6 meters) provides a pulse-separation interval T of approximately 20 ns.

In some embodiments, different fluorophores can be distinguished by their different fluorescent decay rates or characteristic lifetimes. Accordingly, in certain embodiments pulse-separation interval T is sufficient to collect adequate statistics for the selected fluorophores to distinguish between their different decay rates. Adequate pulse-separation interval T enables data handling circuitry to process the data collected by the reaction chambers. In some embodiments, pulse-separation interval T between about 5 ns and about 20 ns is generally suitable for fluorophores that have decay rates up to about 2 ns and for handling data from between about 60,000 and 10,000,000 reaction chambers.

V. Back-Side illumination

In the foregoing examples, integrated device 1-102 is shown in a configuration that receives incident photons in a direction in which photodetection region PPD, charge storage regions SD0 and SD1, and readout region FD are spaced from transfer gates REJ, ST0, TX0, and TX1. As shown in FIG. 1-2, integrated device 1-102 is configured to receive incident photons along the −Y direction at a first side, and metal layers 1-240 are positioned on the first side of integrated device 3-102 that is facing the Y direction. Such a configuration for integrated device 1-102 may sometimes be referred to as a front-side illuminated (FSI) configuration.

Some aspects of the present disclosure relate to structures configured to receive incident photons in other directions and including multiple sequentially-coupled charge storage regions, as described herein for integrated device 1-102. For instance, the inventors recognized that an integrated device configured to receive incident photons in a direction in which the transfer gates are spaced from the photodetection region, charge storage regions, and/or readout region may have improved optical and electrical characteristics because the optical characteristics of the transfer gates have a reduced impact on the incident photons.

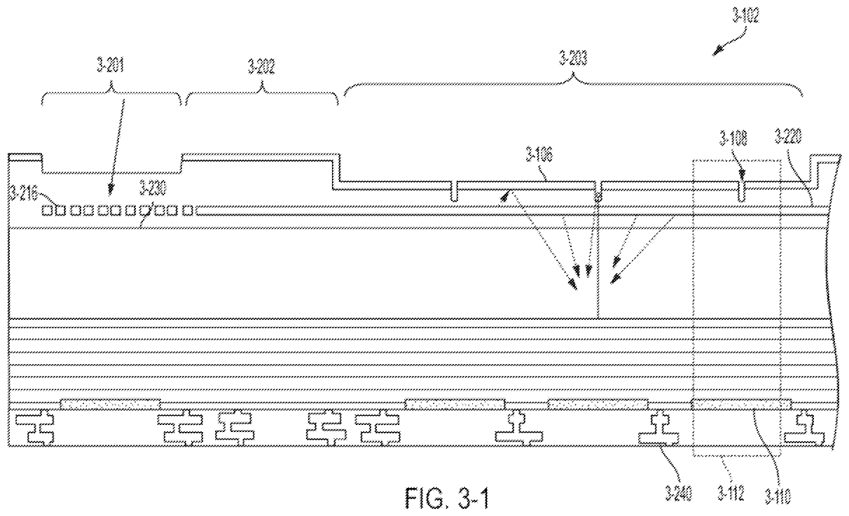

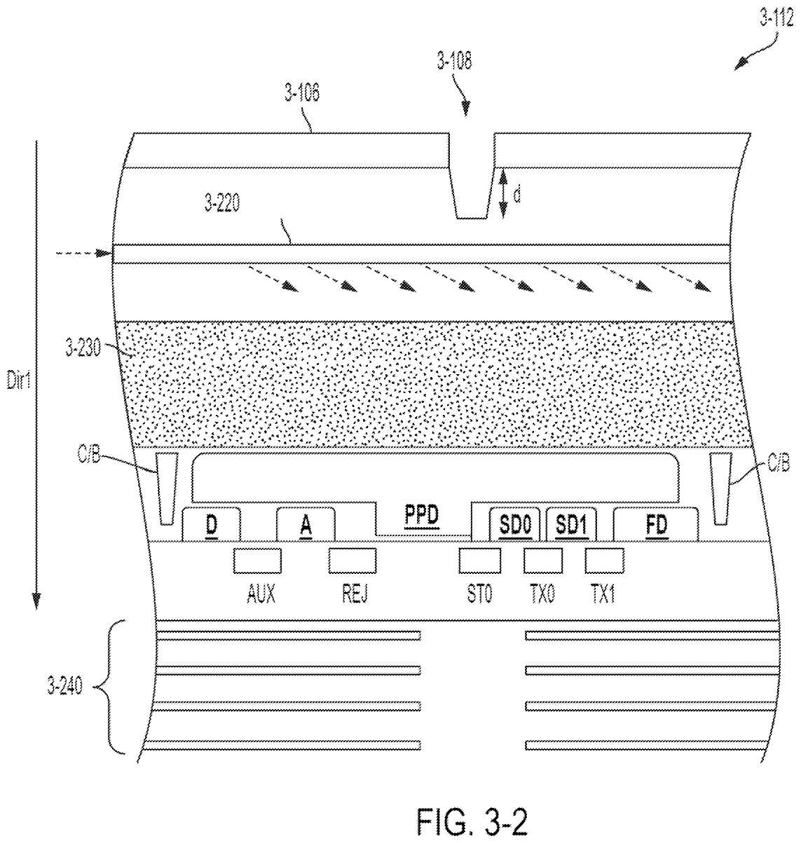

FIG. 3-1 is a cross-sectional schematic of an alternative example integrated device 3-102 illustrating a row of pixels 3-112, according to some embodiments.

In some embodiments, integrated device 3-102 can be configured in the manner described herein for integrated device 1-102. For example, as shown in FIG. 3-1, integrated device 3-102 can include a coupling region 3-201 including one or more grating couplers 3-216, a routing region 3-202 including one or more waveguides 3-220, and a pixel region 3-203 including one or more pixels 3-112. An exemplary pixel 3-112 is indicated by a dotted box in FIG. 3-1 including a sample well 3-108 and a photodetector 3-110. Also shown in FIG. 3-1, integrated device 3-102 can include one or more photonic structures 3-230 positioned between sample wells 3-108 and photodetectors 3-110.

As shown in FIG. 3-1, integrated device 3-102 is shown configured to receive incident photons at a first side, and metal layers 3-240 are positioned on a second side of integrated device 3-102 that is opposite the first side in the direction Dir1 in which integrated device 3-102 is configured to receive incident photons. Such a configuration for integrated device 3-102 may sometimes be referred to as a backside-illuminated (BSI) configuration.

Some examples of BSI configuration that may be applied to some embodiments disclosed herein are described in U.S. patent application Ser. No. 17/507,585, titled “INTEGRATED CIRCUIT WITH SEQUENTIALLY-COUPLED CHARGE STORAGE AND ASSOCIATED TECHNIQUES,” filed Oct. 21, 2021, which is incorporated herein by reference in its entirety.

FIG. 3-2 is a cross-sectional view of an example pixel 3-112 of integrated device 3-102, according to some embodiments. In some embodiments, pixel 3-112 may be configured in the manner described herein for pixel 1-112, pixel 112′, pixel 2-112, pixel 2-112′, and/or any other pixel described herein. For example, as shown in FIG. 3-2, pixel 3-112 can include photodetection region PPD, two charge storage regions SD0 and SD1, readout region FD, drain region D, and transfer gates ST0, TX0, TX1, and REJ. It should be appreciated that pixel 3-112 can include any number of charge storage regions as described herein for pixels 1-112, 1-112′, 2-112, and 2-112′.

As shown in FIG. 3-2, transfer gates AUX, ST0, TX0, TX1, and REJ can be spaced from photodetection region PPD, charge storage regions SD0 and SD1, readout region FD, drain region D and auxiliary region A, in the direction Dir1 in which photodetection region PPD is configured to receive incident photons. Also shown in FIG. 3-2, metal layers 3-240 can be spaced from photodetection region PPD, charge storage regions SD0 and SD1, readout region FD, and drain region D, as well as transfer gates ST0, TX0, TX1, and REJ in the direction Dir1.

In FIG. 3-2, charge storage region SD0 is spaced from photodetection region PPD in a second direction perpendicular to the direction Dir1, charge storage region SD1 is spaced from charge storage region SD0 in the second direction. Also shown in FIG. 3-2, transfer gate ST0 is spaced from photodetection region PPD in the second direction and transfer gate TX0 is spaced from transfer gate ST0 in the second direction. In some embodiments, readout region FD can be spaced from charge storage region SD1 in the second direction and/or transfer gate TX1 can be spaced from transfer gate TX0 in the second direction (e.g., FIGS. 3-3B, 3-4). Alternatively or additionally, in some embodiments, readout region FD can be spaced from charge storage region SD1 in a third direction different from the second direction and/or transfer gate TX1 can be spaced from transfer gate TX0 in the third direction (FIGS. 3-5A, 3-6).

In some embodiments, pixel 3-112 can include one or more charged and/or biased (C/B) regions positioned alongside photodetection region PPD. For example, the C/B regions can include one or more charge layers (e.g., metal-oxide compounds such as aluminum-oxide) within an oxide layer (e.g., silicon dioxide) that intrinsically deplete photodetection region PPD of charge carriers. Alternatively or additionally, the C/B regions can include a conductive material (e.g., metal) configured for coupling to a bias voltage (e.g., supplied by a power supply) to deplete photodetection region PPD of charge carriers when the bias voltage is applied to the C/B regions. The inventors have recognized that C/B regions can increase the rate at which charge carriers generated in photodetection region PPD flow to drain region D and/or charge storage regions SD0 and SD1. In some embodiments, C/B regions can be positioned on each side of photodetection region PPD except the side at which photodetection region PPD is configured to receive incident photons.

Having thus described several aspects and embodiments of the technology of the present disclosure, it is to be appreciated that various alterations, modifications, and improvements will readily occur to those of ordinary skill in the art. Such alterations, modifications, and improvements are intended to be within the spirit and scope of the technology described herein. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. The transitional phrases “consisting of” and “consisting essentially of” shall be closed or semi-closed transitional phrases, respectively.

The terms “approximately,” “substantially,” and “about” may be used to mean within ±20% of a target value and/or aspect in some embodiments, within ±10% of a target value in some embodiments, within ±5% of a target value in some embodiments, and yet within ±2% of a target value in some embodiments. The terms “approximately,” “substantially,” and “about” may include the target value.

What is claimed is:

1. An integrated circuit, comprising:
a photodetection region;
an auxiliary region;
a drain region;
a first transistor channel electrically coupling the photodetection region to the auxiliary region; and
a second transistor channel electrically coupling the auxiliary region to the drain region,
wherein when the first transistor channel is in an on state, the second transistor channel is in an on state.

2. The integrated circuit of claim 1, further comprising a drain transfer gate electrically coupled to the first transistor channel and configured to control a transfer of charge carriers from the photodetection region to the drain region.

3. The integrated circuit of claim 2, wherein the drain transfer gate is configured to receive a control signal to bias the first transistor channel to transfer charge carriers.

4. The integrated circuit of claim 3, further comprising an auxiliary transfer gate electrically coupled to the second transistor channel, wherein the auxiliary transfer gate is conductively coupled to the drain region.

5. The integrated circuit of claim 1, further comprising a pixel comprising the photodetection region, the auxiliary region, and the drain region, wherein the pixel has an area smaller than or equal to 7.5 micrometers×5 micrometers.

6. The integrated circuit of claim 1, wherein the drain region is configured to receive a voltage that is different from the voltage at the photodetection region.

7. The integrated circuit of claim 1, wherein the drain region is configured to receive a direct current (DC) voltage.

8. The integrated circuit of claim 1, wherein the second transistor channel is in an on state only when the first transistor channel is in an on state.

9. The integrated circuit of claim 6, wherein the drain region is configured for coupling to a power supply voltage.

10. The integrated circuit of claim 1, wherein the first transistor channel and the second transistor channel are configured to transfer excitation charge carriers from the photodetection region to the drain region.

11. The integrated circuit of claim 10, wherein the integrated circuit is configured such that a majority of charge carriers transferred via the first transistor channel and via the second transistor channel are excitation photoelectrons.

12. The integrated circuit of claim 1, further comprising a via coupled to the drain region.

13. The integrated circuit of claim 1, wherein the drain region is conductively coupled to a metal layer in the integrated circuit.

14. An integrated circuit, comprising:
a photodetection region;
an auxiliary region;
a drain region;
a drain transistor channel coupled to a drain transfer gate configured to receive a control signal; and
an auxiliary transistor channel coupled to an auxiliary transfer gate,
wherein when a control signal is received at the drain transfer gate, the drain and auxiliary transistor channels are configured to conduct a current from the photodetection region to the drain region via the auxiliary region.

15. The integrated circuit of claim 14, wherein the drain transfer gate is configured to bias the drain transistor channel to conduct a current using the control signal.

16. The integrated circuit of claim 14, wherein a voltage at the auxiliary region is higher than a voltage at the drain region.

17. The integrated circuit of claim 14, wherein the auxiliary transistor channel and the auxiliary transfer gate are conductively coupled to the drain region.

18. The integrated circuit of claim 14, wherein the auxiliary transfer gate is configured to receive a gate control signal having a timing based on the control signal received at the drain transfer gate.

19. The integrated circuit of claim 14, wherein the current conducted from the photodetection region to the drain region via the auxiliary region consists essentially of a plurality of charge carriers, wherein a majority of the plurality of charge carriers are excitation charge carriers.

20. The integrated circuit of claim 14, further comprising a via coupled to the drain region.

21. The integrated circuit of claim 14, wherein the drain region is conductively coupled to a metal layer in the integrated circuit.

22. An integrated circuit, comprising:
a photodetection region;
an auxiliary region;
a drain region;
a drain device electrically coupling the photodetection region to the auxiliary region; and
an auxiliary device electrically coupling the auxiliary region to the drain region,
wherein the auxiliary device comprises a transistor in a diode-connected configuration.

23. The integrated circuit of claim 22, wherein the drain region is configured for coupling to a direct current (DC) voltage source.

24. The integrated circuit of claim 23, further comprising:
a drain transfer gate electrically coupled to the drain device and configured to control a transfer of charge carriers from the photodetection region to the drain region.

25. The integrated circuit of claim 24, wherein the drain transfer gate is configured to receive a control signal to bias the drain device to transfer charge carriers using the control signal.

26. The integrated circuit of claim 22, further comprising a pixel comprising the photodetection region, the auxiliary region, and the drain region, wherein the pixel has an area smaller than or equal to 7.5 micrometers×5 micrometers.

27. The integrated circuit of claim 22, wherein the auxiliary device further comprises an auxiliary transfer gate electrically coupled to the auxiliary device.

28. The integrated circuit of claim 27, wherein the auxiliary transfer gate is conductively coupled to the drain region.

29. The integrated circuit of claim 22, wherein the transistor is a first transistor, and the auxiliary device further comprises a second transistor in a diode-connected configuration.

30. The integrated circuit of claim 29, wherein the first transistor and the second transistor are connected in series or in parallel.
